(19) United States
(12) Patent Application Publication
(10) Pub. No.: US 2016/0353571 A1
(43) Pub. Date: Dec. 1, 2016

(54) CARRIER DEVICE AND SUBSTRATE ASSEMBLY INCLUDING SAME

(71) Applicant: HON HAI PRECISION INDUSTRY CO., LTD., New Taipei (TW)

(72) Inventors: JEN-TSORNG CHANG, New Taipei (TW); FENG-YUEN DAI, New Taipei (TW)

(21) Appl. No.: 14/882,924

(22) Filed: Oct. 14, 2015

(30) Foreign Application Priority Data
May 26, 2015 (CN) 201510273334.0

(51) Int. Cl. H05K 1/09; H05K 1/18; H05K 1/11

(52) U.S. Cl. CPC H05K 1/09; H05K 1/115; H05K 1/18

(57) ABSTRACT

A carrier device includes a carrier glass and a carbon nanotube layer. The carrier glass includes a top surface and a bottom surface opposite to the top surface. The carbon nanotube layer is positioned on the top surface. The carbon nanotube layer includes a start conductive terminal, an end conductive terminal, and carbon nanotubes. The start conductive terminal is electrically connecting to the end conductive terminal via the carbon nanotubes. The start conductive terminal electrically connects to a voltage source. The end conductive terminal electrically connects to the ground via a capacitor.

### FIELD

The subject matter herein generally relates to liquid crystal panel manufacturing technologies, and particularly to a carrier device for liquid crystal display panels and a substrate assembly including the carrier device.

### BACKGROUND

Liquid crystal display panels include thin film transistor array substrates, color filters, and liquid crystal molecules between the thin film transistor array substrates and the color filters. In manufacturing the thin film transistor array substrates, a thick glass sheet is applied and then thin film transistor array and pixel electrodes are formed on the thick glass sheet. Finally, the thickness of the glass sheet with the thin film transistor array and the pixel electrodes is reduced by chemical means. In reducing the thickness of the glass sheet, hydrofluoric acid is applied. However, hydrofluoric acid is a strong acid and is not environmentally friendly.

Therefore, to avoid using the hydrofluoric acid, a supper thin glass sheet is applied. The thin film transistor array and the pixel electrodes are formed on the supper thin glass sheet. The supper thin glass sheet generally has a thickness in a range of 0.02 mm-0.2 mm. In forming the thin film transistor array and the pixel electrodes, the super thin glass sheet is easy to be curved or deformed. To solve the problem, in forming the thin film transistor array and the pixel electrodes, a thick carrier glass is bonded to the super thin glass sheet by glue. After the thin film transistor array and the pixel electrodes are formed, the super thin glass sheet is peeled off from the thick carrier glass.

### BRIEF DESCRIPTION OF THE DRAWINGS

Implementations of the present technology will now be described, by way of example only, with reference to the attached figures.

FIG. 1 is a cross-sectional diagram illustrating a first embodiment of a carrier device of the present disclosure.

FIG. 2 is a diagram illustrating a carbon nanotube layer of the carrier device of FIG. 1.

FIG. 3 is a cross-sectional diagram illustrating a second embodiment of a carrier device of the present disclosure.

FIG. 4 is a cross-sectional diagram of a third embodiment of a substrate assembly of the present disclosure.

FIG. 5 is a cross-sectional diagram illustrating a fourth embodiment of a substrate assembly of the present disclosure.

FIG. 6 is a cross-sectional diagram illustrating a fifth embodiment of a substrate assembly of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proterminalions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

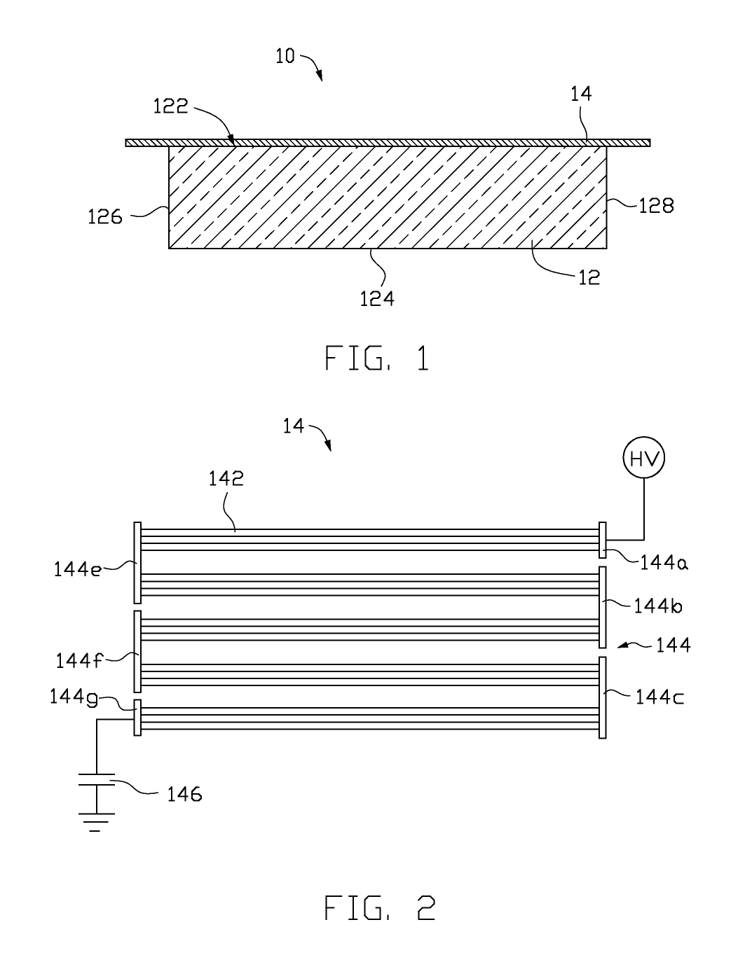

Referring to FIG. 1, a first embodiment of a carrier device 10 is shown. The carrier device 10 includes a carrier glass 12 and a carbon nanotube layer 14.

The carrier glass 12 is substantially rectangular shaped. The carrier glass 12 includes a top surface 122, a bottom surface 124, a first side surface 126, and a second side surface 128. The top surface 122 and the bottom surface 124 are positioned at two sides of the carrier glass 12 and are opposite to each other. The top surface 122 is parallel to the bottom surface 124. Similarly, the first side surface 126 and the second side surface 128 are positioned at two sides of the carrier glass 12 and are opposite to each other. The first side surface 126 is parallel to the side surface 128. The first and second side surfaces 126, 128 are both perpendicularly connected to the top surface 122 and the bottom surface 124. In at least one embodiment, the carrier glass 12 has a thickness in a range of 0.5-0.8 millimeters, i.e., a distance between the top surface 122 and the bottom surface 124 is in a range of 0.5-0.8 millimeters. In other embodiments, the first side surface 126 and the second side surface 128 are both inclinedly connected to the top surface 122 and the bottom surface 124.

Referring also to FIG. 2, the carbon nanotube layer 14 is combined to the top surface 122 through welding technology and projects out of the first and second side surfaces 126, 128. In at least one embodiment, the carbon nanotube layer 14 includes a plurality of carbon nanotubes 142 and a plurality of conductive pins 144. The carbon nanotubes 142 are parallel to and separated from each other. An extension direction of each carbon nanotube 142 is perpendicular to the first and second side surfaces 126, 128. The conductive pins 144 are positioned on the carbon nanotube layer 14 and arranged in two groups. The first group of conductive pins 144 are positioned on a side of the carbon nanotube layer 14 and are close to the first side surface 126, while the second group of conductive pins 144 are positioned on another side of the carbon nanotube layer 14 and are close to the second side surface 128. The conductive pins 144 in each group are separated from each other. Each conductive pin 144 electrically connects to ends of some of the carbon nanotubes 142. In the illustrated embodiment, the first conductive pin 144a in the second group is connected to a high voltage, and the third conductive pin 144g in the first group is electrically connected to the group through a capacitor 146. As a result, the high voltage is transmitted through the first conductive pin 144a, a first carbon nanotube 142, the first conductive pin 144e in the first group, a second carbon nanotube 142, a second conductive pin 144b in the second group 144, a third carbon nanotube 142, a third conductive pin 144c in the second group, a fourth carbon nanotube 142, the third conductive pin 144g in the first group and is finally electrically connected to the ground through the capacitor 146, so as to constitute an electrical circuit. The first conductive pin 144a in the second group is treated as a start conductive terminal of the carbon nanotube layer 14, and the third conductive pin 144g in the second group is treated as an end conductive terminal of the carbon nanotube layer 14. The start conductive terminal is positioned on a portion of the carbon nanotube layer 14 which is projecting out of the first side surface 126. The end conductive terminal of the carbon nanotube layer 14 is positioned on another portion of the carbon nanotube layer 14 which is projecting out of the second side surface 128. In other embodiments, the carbon nanotubes 142 and the conductive pins 144 can be arranged in other manners, so long as the high voltage is input to the start conductive terminal and then transmitted through the carbon nanotubes 142 and other conductive pins and is finally output through the end conductive terminal, so as to constitute an electrical circuit.

Because a node between two carbon nanotubes 142 has a high electrical impedance, the carbon nanotube layer 14 generates static force when applied by the high voltage. When the carrier device 10 moves close to an object, for example, a glass substrate 30 as shown in FIG. 4, the static force sucks the glass substrate 30 onto the carbon nanotube layer 14. When the high voltage is turned off, the static force disappears and the glass substrate 30 peels off from the carbon nanotube layer 14. As a result, glue is avoided to be used, so as to prevent the carrier glass 12 from damaging when the glass substrate 30 peeling off from the carbon nanotube layer 14. In other embodiments, a negative static force can be generated to delete the static force generated by the carbon nanotube layer 14, such that the glass substrate 30 peels off from the carrier device 10.

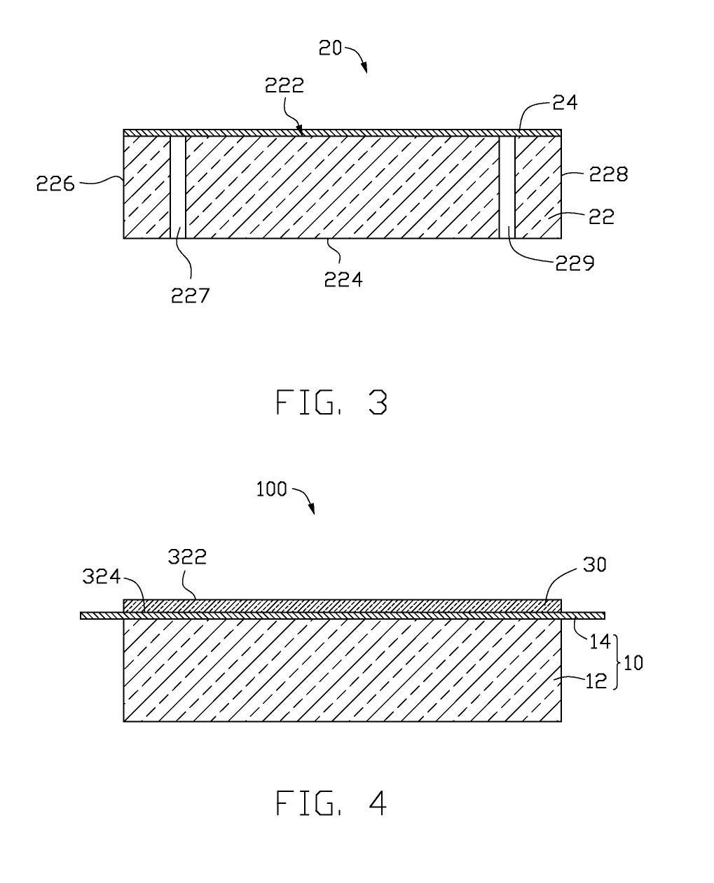

Referring to FIG. 3, a second embodiment of a carrier device 20 is shown. The carrier device 20 includes a carrier glass 22 and a carbon nanotube layer 24.

The carrier glass 22 is substantially rectangular shaped. The carrier glass 22 includes a top surface 222, a bottom surface 224, a first side surface 226, and a second side surface 228. The top surface 222 and the bottom surface 224 are positioned at two sides of the carrier glass 22 and are opposite to each other. The top surface 222 is parallel to the bottom surface 224. Similarly, the first side surface 226 and the second side surface 228 are positioned at two sides of the carrier glass 22 and are opposite and parallel to each other. The first side surface 226 and the second side surface 228 are both perpendicularly connected to the top surface 222 and the bottom surface 224. In at least one embodiment, the carrier glass 22 has a thickness in a range of 0.5-0.8 millimeters, i.e., a distance between the top surface 222 and the bottom surface 224 is in a range of 0.5-0.8 millimeters. The carrier glass 22 defines a first conductive through hole 227 and a second conductive through hole 229 both passing through the top surface 222 and the bottom surface 224. The first conductive through hole 226 is close to the first side surface 226 and is spatially close to an end conductive terminal. The end conductive terminal is electrically connected to the capacitor and then is electrically connected to the ground through the first conductive through hole 226. The second conductive through hole 229 is close to the second side surface 228 and is spatially corresponding to a star conductive terminal. The high voltage is electrically connected to the star conductive terminal through the second conductive through hole 229. The first and second conductive through holes 227, 229 are both formed by laser drill technology.

The carbon nanotube layer 24 is combined to the top surface 222 by welding technology, but not projecting out of the first side surface 226 and the second side surface 228. In the illustrated embodiment, two sides of the carbon nanotube layer 24 are coplanar with the first side surface 226 and the second side surface 228. The arrangement of the carbon nanotubes and the conductive pins in the carbon nanotube layer 24 are the same as the arrangement of the carbon nanotubes 142 and the conductive pins 144 in the carbon nanotube layer 14.

Referring to FIG. 4, a third embodiment of a substrate assembly 100 is shown. The substrate assembly 100 includes the carrier device 10 of the first embodiment and the glass substrate 30.

The glass substrate 30 is substantially rectangular shaped. The glass substrate 30 includes a first surface 322 and a second surface 324. The first and second surfaces 322, 324 are positioned at two sides of the glass substrate 30 and are opposite and parallel to each other. In at least one embodiment, the glass substrate 30 has a thickness in a range of 0.02-0.2 millimeters, i.e., a distance between the first surface 322 and the second surface 324 is in a range of 0.02-0.2 millimeters.

The carrier device 10 generates the static force and then moves close to the second surface 324 of the glass substrate 30. Because the glass substrate 30 is uncharged, the static force generated by the glass substrate 30 sucks the second surface 324 of the glass substrate 30, so as to facilitate workers to process the glass substrate 30. When the high voltage is turned off, the static force disappears and the glass substrate 30 peels off from the carrier device 10. In other embodiments, a negative static force is generated to delete the static force generated by the carbon nanotube layer 14.

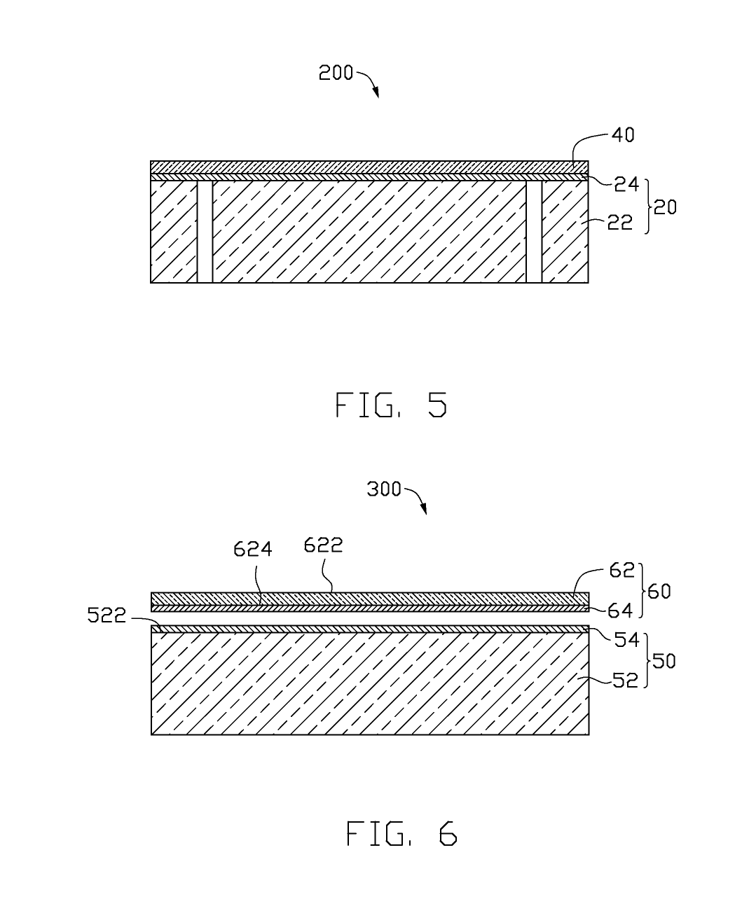

Referring to FIG. 5, a fourth embodiment of a substrate assembly 200 is substantially the same as the third embodiment of the substrate assembly 100, except that the substrate assembly 200 includes the carrier device 20 of the second embodiment.

Referring to FIG. 6, a fifth embodiment of a substrate assembly 300 includes a carrier device 50 and a glass substrate 60.

The carrier device 50 includes a carrier glass 52 and a first carbon nanotube layer 54. The carrier glass 52 is the same as the carrier glass 12 of the carrier device 10 of the first embodiment. The first carbon nanotube layer 54 is combined to a top surface 522 of the carrier glass 52. Two sides of the first carbon nanotube layer 54 are coplanar with the first side surface 526 and the second side surface 528.

The glass substrate 60 includes a substrate body 62 and a second carbon nanotube layer 64. The substrate body 62 includes a first surface 622 and a second surface 624, the second carbon nanotube layer 64 is combined to the second surface 624 through welding technology.

The arrangement of the carbon nanotubes and the conductive pins in the first and second carbon nanotube layers 54, 64 are the same as the arrangement of the carbon nanotube 142 and the conductive pins 144 of the carbon nanotube layer 14 in the first embodiment.

In use, the first carbon nanotube layer 54 is supplied by a voltage and the second carbon nanotube 64 is electrically connected to the ground. As a result, the first carbon nanotube layer 54 is the positive electrode of a capacitor, while the second carbon nanotube layer 64 is the negative electrode of the capacitor. The carrier device 50 with the first carbon nanotube layer 54 generate a static force with respective to the glass substrate 60 with the second carbon nanotube layer 64, so as to suck the glass substrate 60 to the carrier device 50. When the voltage applied to the first carbon nanotube layer 54 is turned off, the static force generated between the first carbon nanotube layer 54 and the second carbon nanotube layer 64 disappears and the glass substrate 60 peels off from the carrier device 50. In other embodiments, the first carbon nanotube layer 54 can be electrically connected to the ground, while the second carbon nanotube layer 64 can be supplied by the voltage.

The carrier device 10, 20 and the substrate assembly 100, 200, 300 suck the glass substrate through the static force and avoid using glue, so as to prevent the glass substrate from damaging when peeling off from the carrier device 10, 20.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A carrier device, comprising:
a carrier glass having a top surface and a bottom surface opposite to the top surface; and
a carbon nanotube layer positioned on the top surface, the carbon nanotube layer comprising a start conductive terminal, an end conductive terminal, and a plurality of carbon nanotubes, the start conductive terminal electrically coupled to the end conductive terminal via the carbon nanotubes, the start conductive terminal configured to connect to a voltage source, the end conductive terminal configured to electrically connect to ground via a capacitor.

2. The carrier device of claim 1, wherein a distance between the top surface and the bottom surface is in a range of 0.5-0.8 millimeters.

3. The carrier device of claim 1, wherein the carbon nanotube layer is welded on the top surface.

4. The carrier device of claim 1, wherein the carrier glass comprises a first side surface and a second side surface opposite to the first side surface, two sides of the carbon nanotube layer are projecting out of the first side surface and the second side surface, and the start conductive terminal and the end conductive terminal are individually positioned on the portions of the carbon nanotube layer which are projecting out of the first and second side surfaces.

5. The carrier device of claim 1, wherein the carrier glass comprises a first side surface and a second side surface opposite to the first side surface, the carrier glass defines two conductive through holes, one of the conductive through holes is close to the first side surface, and another of the conductive through holes is close to the second side surface.

6. The carrier device of claim 5, wherein two sides of the carbon nanotube layer are coplanar with the first side surface and the second side surface, the start conductive terminal is configured to connect to the voltage source via one of the conductive through holes, and the end conductive terminal is configured to connect to the capacitor and the ground through another of the conductive through holes.

7. The carrier device of claim 1, wherein the carbon nanotubes are parallel to and separated from each other, the carbon nanotube layer comprises a plurality of conductive terminals, the conductive terminals are electrically connected to two ends of the carbon nanotubes, one of the conductive terminals is the start conductive terminal, and another of the conductive terminals is the end conductive terminal.

8. A substrate assembly, comprising:
a glass substrate has a thickness in a range of 0.02-0.2 millimeters; and
a carrier device, comprising:
a carrier glass having a top surface and a bottom surface opposite to the top surface; and
a carbon nanotube layer positioned on the top surface, the carbon nanotube layer comprising a start conductive terminal, an end conductive terminal, and a plurality of carbon nanotubes, the start conductive terminal electrically coupled to the end conductive terminal via the carbon nanotubes, the start conductive terminal configured to connect to a voltage source, the end conductive terminal configured to electrically connect to ground via a capacitor, the carbon nanotube layer configured to generate a static force to suck the glass substrate on the carrier device.

9. The substrate assembly of claim 8, wherein a distance between the top surface and the bottom surface is in a range of 0.5-0.8 millimeters.

10. The substrate assembly of claim 8, wherein the carbon nanotube layer is welded on the top surface.

11. The substrate assembly of claim 8, wherein the carrier glass comprises a first side surface and a second side surface opposite to the first side surface, two sides of the carbon nanotube layer are projecting out of the first side surface and the second side surface, and the start conductive terminal and the end conductive terminal are individually positioned on the portions of the carbon nanotube layer which are projecting out of the first and second side surfaces.

12. The substrate assembly of claim 8, wherein the carrier glass comprises a first side surface and a second side surface opposite to the first side surface, the carrier glass defines two conductive through holes, one of the conductive through holes is close to the first side surface, and another of the conductive through holes is close to the second side surface.

13. The substrate assembly of claim 12, wherein two sides of the carbon nanotube layer are coplanar with the first side surface and the second side surface, the start conductive terminal is configured to connect to the voltage source through one of the conductive through holes, and the end conductive terminal is configured to connect to the capacitor and the ground through another of the conductive through holes.

14. The substrate assembly of claim 8, wherein the carbon nanotubes are parallel to and separated from each other, the carbon nanotube layer comprises a plurality of conductive terminals, the conductive terminals are electrically connected to two ends of the carbon nanotubes, one of the conductive terminals is the start conductive terminal, and another of the conductive terminals is the end conductive terminal

15. A substrate assembly, comprising:
a carrier device, comprising:
a carrier glass having a top surface and a bottom surface opposite to the top surface; and
a first carbon nanotube layer positioned on the top surface, the carbon nanotube layer comprising a start conductive terminal, an end conductive terminal, and a plurality of carbon nanotubes, the start conductive terminal electrically connecting to the end conductive terminal via the carbon nanotubes;
a glass substrate having a thickness in a range of 0.02-0.2 millimeters, the glass substrate comprising:
a substrate body having a first surface and a second surface opposite to the first surface;
a second carbon nanotube layer positioned on the second surface, the first and second carbon nanotube layers configured to cooperatively generate a static force to suck the glass substrate and the carrier device together.

16. The substrate assembly of claim 15, wherein the first carbon nanotube layer is electrically connected to a voltage source, and the second carbon nanotube layer is electrically connected to ground.

17. The substrate assembly of claim 15, wherein the first carbon nanotube layer is electrically connected to ground, and the second carbon nanotube layer is electrically connected to a voltage source.

18. The substrate assembly of claim 15, wherein the carrier glass comprises a first side surface and a second side surface opposite to the first side surface, two sides of the carbon nanotube layer are projecting out of the first side surface and the second side surface, and the start conductive terminal and the end conductive terminal are individually positioned on the portions of the carbon nanotube layer which are projecting out of the first and second side surfaces.

19. The substrate assembly of claim 15, wherein the carrier glass comprises a first side surface and a second side surface opposite to the first side surface, the carrier glass defines two conductive through holes, one of the conductive through holes is close to the first side surface, and another of the conductive through holes is close to the second side surface.

20. The substrate assembly of claim 19, wherein two sides of the carbon nanotube layer are coplanar with the first side surface and the second side surface.
